(19) United States
(12) Patent Application Publication
(10) Pub. No.: US 2017/0288151 A1
(43) Pub. Date: Oct. 5, 2017

(54) COMPOSITION FOR FORMING ORGANIC SEMICONDUCTOR FILM AND ORGANIC SEMICONDUCTOR ELEMENT

(71) Applicant: FUJIFILM CORPORATION, Tokyo (JP)

(72) Inventors: Yuta SHIGENOI, Kanagawa (JP); Tetsu KITAMURA, Kanagawa (JP)

(21) Appl. No.: 15/622,076

(22) Filed: Jun. 14, 2017

Related U.S. Application Data
(63) Continuation of application No. PCT/JP2016/057099, filed on Mar. 8, 2016.

(30) Foreign Application Priority Data
Mar. 11, 2015 (JP) 2015-048522

(51) Int. Cl. H01L 51/00; C09D 11/033; C09D 11/52; C09D 11/102; C09D 11/36

(52) U.S. Cl. CPC H01L 51/0074; H01L 51/0007; H01L 51/0068; H01L 51/0094; C09D 11/102; C09D 11/36; C09D 11/52; C09D 11/033; H01L 51/0005; H01L 51/0004; H01L 51/0558

(57) ABSTRACT

A composition for forming an organic semiconductor film includes an organic semiconductor represented by the following Formula A-1, and a solvent having a boiling point of from 150° C. to 300° C. and an SP value of from 15.0 to 18.0.

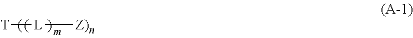

### CROSS-REFERENCE TO RELATED APPLICATIONS

This application is a continuation application of International Application No. PCT/JP2016/057099, filed Mar. 8, 2016, the disclosure of which is incorporated herein by reference in its entirety. Further, this application claims priority from Japanese Patent Application No. 2015-048522, filed Mar. 11, 2015, the disclosure of which is incorporated herein by reference in its entirety.

### BACKGROUND OF THE INVENTION

### 1. Field of the Invention

The present invention relates to a composition for forming an organic semiconductor film and an organic semiconductor element.

### 2. Description of the Related Art

An organic transistor having an organic semiconductor film (organic semiconductor layer) is used in a field effect transistor (FET) used in a liquid crystal display or an organic EL display, a Radio Frequency Identifier (RFID, RF tag), and the like, because the use of the organic transistor makes it possible to achieve lightening of weight and cost reduction and to achieve flexibilization.

As organic semiconductors of the related art, those described in JP2009-267132A and JP2012-510454A are known.

### SUMMARY OF THE INVENTION

An object of the present invention is to provide a composition for forming an organic semiconductor film that makes it possible to obtain an organic semiconductor element having high mobility and is excellent in film formability. Another object of the present invention is to provide an organic semiconductor element using the composition for forming an organic semiconductor film.

The objects of the present invention are achieved by means described below in <1> or <7>. Preferred embodiments are also described below in <2> to <6>.

<1> A composition for forming an organic semiconductor film, comprising an organic semiconductor represented by the following Formula A-1 as Component A, and a solvent, which has a boiling point of equal to or higher than 150° C. and equal to or lower than 300° C. and an SP value of equal to or higher than 15.0 and equal to or lower than 18.0, as Component B.

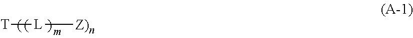

In Formula A-1, T represents an aromatic hydrocarbon group having a ring-fused structure including 3 or more rings or a heteroaromatic group; L each independently represents a phenylene group or a thienylene group; Z each independently represents a group represented by the following Formula a-1; m each independently represents an integer of 0 to 4; n represents an integer of 1 to 8; and in a case where T does not have a ring-fused structure including 5 or more rings, m represents an integer of 1 to 4, and n represents an integer of 2 to 8.

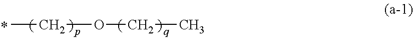

In Formula a-1, p represents an integer of 1 to 20, q represents an integer of 0 to 20, and * represents a binding position with respect to other structures.

<2> The composition for forming an organic semiconductor film described in <1>, further comprising a silicone compound having a structure represented by the following Formula D-1.

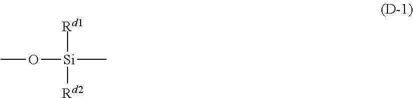

In Formula D-1, R^{d1} and R^{d2} each independently represent a monovalent hydrocarbon group which does not contain an ether bond.

<3> The composition for forming an organic semiconductor film described in <2>, in which in Formula D-1, at least one of R^{d1} or R^{d2} is an alkyl group having 2 to 18 carbon atoms or an alkenyl group having 2 to 18 carbon atoms.

<4> The composition for forming an organic semiconductor film described in any one of <1> to <3>, in which in Formula A-1, T contains an acene, phenacene, or heteroacene structure having a ring-fused structure including 3 to 7 rings.

<5> The composition for forming an organic semiconductor film described in any one of <1> to <4>, in which Component A is an organic semiconductor represented by the following Formula A-2.

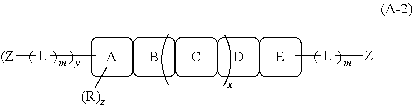

In Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L represents a phenylene group or a thienylene group; Z represents a group represented by Formula a-1; m represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of rings A to E is C₂, C₂ᵥ, or C₂ₕ.

<6> The composition for forming an organic semiconductor film described in any one of <1> to <5>, in which in Formula a-1, p is an integer of 1 to 6.

<7> An organic semiconductor element manufactured using the composition for forming an organic semiconductor film described in any one of <1> to <6>.

According to the present invention, it is possible to provide a composition for forming an organic semiconductor film that makes it possible to obtain an organic semiconductor element having high mobility and is excellent in film formability. Furthermore, according to the present invention, it is possible to provide an organic semiconductor element using the composition for forming an organic semiconductor film.

### BRIEF DESCRIPTION OF THE DRAWINGS

FIG. 1 is a schematic cross-sectional view of an aspect of an organic semiconductor element of the present invention.

FIG. 2 is a schematic cross-sectional view of another aspect of the organic semiconductor element of the present invention.

### DESCRIPTION OF THE PREFERRED EMBODIMENTS

Hereinafter, the contents of the present invention will be specifically described. The constituents in the following description will be explained based on typical embodiments of the present invention, but the present invention is not limited to the embodiments. In the specification of the present application, “to” is used to mean that the numerical values listed before and after “to” are a lower limit and an upper limit respectively. Furthermore, in the present invention, an organic EL element refers to an organic electroluminescence element.

In the present specification, in a case where there is no description regarding whether a group (atomic group) is substituted or unsubstituted, the group includes both of a group having a substituent and a group not having a substituent. For example, an “alkyl group” includes not only an alkyl group not having a substituent (unsubstituted alkyl group) but also an alkyl group having a substituent (substituted alkyl group).

In the present specification, in some cases, a chemical structural formula is described as a simplified structural formula in which a hydrogen atom is omitted.

In the present invention, “% by mass” and “% by weight” have the same definition, and “part by mass” and “part by weight” have the same definition.

In the present invention, a combination of preferred aspects is more preferable.

(Composition for forming organic semiconductor film)

The composition for forming an organic semiconductor film (hereinafter, simply referred to as “composition” as well) of the present invention contains an organic semiconductor represented by the aforementioned Formula A-1 as Component A and a solvent, which has a boiling point of equal to or higher than 150° C. and equal to or lower than 300° C. and an SP value of equal to or higher than 15.0 and equal to or lower than 18.0, as Component B.

As a result of repeating a thorough examination, the inventors of the present invention found that by adopting the composition for forming an organic semiconductor film containing Component A and Component B described above, the obtained organic semiconductor film or organic semiconductor element has high mobility, and the film formability of the composition is excellent. Based on what they had found, the inventors accomplished the present invention.

The detail of the mechanism that brings about the aforementioned effects is unclear. However, it is considered that because Component A has an alkoxyalkyl group (group represented by Z in Formula A-1) on a terminal, the solubility in a solvent may be improved, and because Component B having an SP value within a specific range is used as a solvent, the wettability of the composition for forming an organic semiconductor film may be improved.

Presumably, as a result, a composition for forming an organic semiconductor film may be obtained which makes it possible to obtain an organic semiconductor element having high mobility even if a printing method is used.

Hereinafter, each component used in the composition for forming an organic semiconductor film of the present invention will be described.

<Component A: Organic Semiconductor Represented by Formula A-1>

The composition for forming an organic semiconductor film of the present invention contains an organic semiconductor (hereinafter, referred to as “specific compound” as well) represented by the following Formula A-1 as Component A.

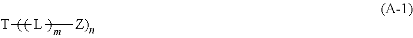

In Formula A-1, T represents an aromatic hydrocarbon group having a ring-fused structure including 3 or more rings or a heteroaromatic group, L each independently represents a phenylene group or a thienylene group, Z each independently represents a group represented by the following Formula a-1, m each independently represents an integer of 0 to 4, and n represents an integer of 1 to 8. In a case where n is equal to or greater than 2, a plurality of m's may be the same as or different from each other. Here, in a case where T does not have a ring-fused structure including 5 or more rings, m represents an integer of 1 to 4, and n represents an integer of 2 to 8.

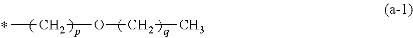

In Formula a-1, p represents an integer of 1 to 20, q represents an integer of 0 to 20, and * represents a binding position with respect to other structures.

Component A can be suitably used in an organic semiconductor element, an organic semiconductor film, and a composition for forming an organic semiconductor film.

Component A is a compound in which an alkoxyalkyl group (Z) represented by Formula a-1 is bonded to an organic semiconductor mother nucleus (T) through a linking group (L) as necessary, and the linking group is selected from the group consisting of a phenylene group, a thienylene group, and a group in which a plurality of phenylene groups or thienylene groups are bonded to each other.

In Formula A-1, T represents an aromatic hydrocarbon group having a ring-fused structure including 3 or more rings or a heteroaromatic group (aromatic heterocyclic group). T is a group obtained by the fusion of 3 or more aromatic rings and exhibits aromaticity. Examples of the aromatic rings include an aromatic hydrocarbon ring (for example, a benzene ring), and an aromatic heterocyclic ring (for example, a thiophene ring, a furan ring, a pyrrole ring, a selenophene ring, or an imidazole ring).

T has a ring-fused structure including 3 or more rings. From the viewpoint of the mobility of an organic semiconductor, T preferably includes 3 to 9 rings, more preferably includes 3 to 7 rings, and even more preferably includes 3 to 6 rings.

It is preferable that at least one of the aromatic rings included in T is preferably an aromatic heterocyclic ring. It is more preferable that the aromatic rings contain, as a heteroatom, at least one kind of atom selected from the group consisting of a sulfur atom, a nitrogen atom, a selenium atom, and an oxygen atom. From the viewpoint of the mobility of an organic semiconductor, the aforementioned heteroatom is more preferably contained in 2 to 6 rings, and even more preferably contained in 2 to 4 rings.

From the viewpoint of the mobility of an organic semiconductor, the aforementioned aromatic heterocyclic ring preferably contains one heteroatom.

Furthermore, from the viewpoint of mobility of an organic semiconductor, T preferably has at least a thiophene ring structure and/or a selenophene ring structure, more preferably has at least a thiophene ring structure. It is even more preferable that all of the heterocyclic structures that T has are thiophene rings structures.

The organic semiconductor represented by Formula A-1 contains a group represented by T, and the group is preferably contained in the compound as a main component. Herein, the “main component” means that the molecular weight-based content of a condensed polycyclic aromatic group is equal to or greater than 30% with respect to the total molecular weight of the organic semiconductor represented by Formula A-1. The content of the main component is preferably equal to or greater than 40%. The upper limit of the content of the main component is not particularly limited, but from the viewpoint of solubility, the upper limit is preferably equal to or less than 80%.

In Formula A-1, T is preferably a structure in which aromatic heterocyclic rings and/or benzene rings are fused with each other in the form of a line (including a straight-line shape and a zigzag pattern). T more preferably contains an acene, phenacene, or heteroacene structure having a ring-fused structure including 3 to 7 rings. Acene is a compound in which benzene rings are linearly fused with each other such that an angle formed between the benzene rings becomes 180° . Specific examples thereof include naphthalene, anthracene, tetracene, pentacene, hexacene, heptacene, and the like. Phenacene is a compound in which benzene rings are fused with each other in a zigzag pattern, and specific examples thereof include phenanthrene, chrysene, picene, and the like. Heteroacene means a compound obtained by substituting some of benzene rings of acene or phene with an aromatic heterocyclic ring (for example, a furan ring, a thiophene ring, or a pyrrole ring). Phene is a compound in which benzene rings are fused in patterns including a zigzag pattern, and all of the phenacenes having a zigzag structure are included in phene. Specific examples of hydrocarbons which are included in phene but are not included in phenacene include benzo[a]anthracene, benzo[c]phenanthrene, dibenzo[a,h]anthracene, dibenzo[a,j]anthracene, dibenzo[c,g]phenanthrene, pentaphene, and the like.

In the specific compound, T as an organic semiconductor mother nucleus preferably contains a heteroacene skeleton in which aromatic heterocyclic rings and/or benzene rings are linearly fused with each other. T is more preferably a thienoacene structure in which thiophene rings and/or benzene rings are linearly fused with each other, and even more preferably a thienoacene structure including 3 to 7 rings fused with each other. If the aforementioned aspect is adopted, an organic semiconductor layer or film having higher mobility is obtained.

From the viewpoint of the mobility of an organic semiconductor, the number of thiophene rings in the condensed polycyclic aromatic group is preferably 2 to 7, more preferably 3 to 7, even more preferably 3 to 5, and particularly preferably 3.

The aromatic hydrocarbon group or the heteroaromatic group having the ring-fused structure that T has may have a substituent.

Examples of the substituent include a halogen atom, an alkyl group (including a cycloalkyl group, a bicycloalkyl group, and a tricycloalkyl group), an alkenyl group, an alkynyl group, an aryl group, a heterocyclic group (may be referred to as a heterocyclic group as well), a cyano group, a hydroxy group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, alkoxycarbonylamino group, an aryloxycarbonylamino group, a sulfamoylamino group, alkyl- and arylsulfonylamino groups, a mercapto group, an alkylthio group, an arylthio group, a heterocyclic thio group, a sulfamoyl group, a sulfo group, alkyl- and arylsulfinyl groups, alkyl- and arylsulfonyl groups, an acyl group, an aryloxycarbonyl group, an alkoxycarbonyl group, a carbamoyl group, aryl- and heterocyclic azo groups, an imide group, a phosphino group, a phosphinyl group, a phosphinyloxy group, a phosphinylamino group, a phosphono group, a silyl group (a trialkylsilyl group or the like), a hydrazino group, a ureido group, a boronic acid group (—B(OH)₂), a phosphato group (—OPO(OH)₂), a sulfato group (—OSO₃H), and other known substituents. These substituents may be further substituted with a substituent.

Among these, as the substituent, a halogen atom, an alkyl group, an alkenyl group, an alkoxy group, an alkylthio group, and an aryl group are preferable, a fluorine atom, a substituted or unsubstituted alkyl group having 1 to 3 carbon atoms, a substituted or unsubstituted alkoxy group having one or two carbon atoms, a substituted or unsubstituted methylthio group, and a phenyl group are more preferable, and a fluorine atom, a substituted or unsubstituted alkyl group having 1 to 3 carbon atoms, a substituted or unsubstituted alkoxy group having one or two carbon atoms, and a substituted or unsubstituted methylthio group are particularly preferable.

Specific examples of the organic semiconductor mother nucleus represented by T in Formula A-1 preferably include the following condensed polycyclic aromatic groups. In these condensed polycyclic aromatic groups, the aforementioned substituent other than a monovalent group represented by -(L)ₘ—Z described above may be bonded onto an aromatic ring and/or an aromatic heterocyclic ring.

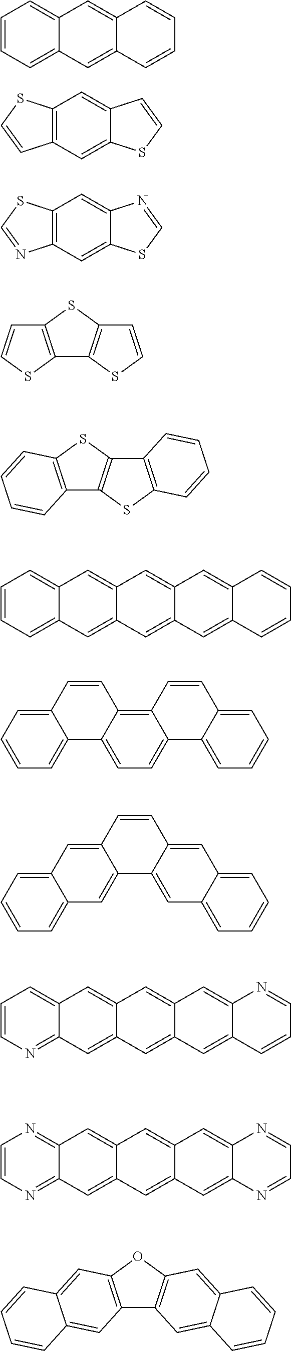

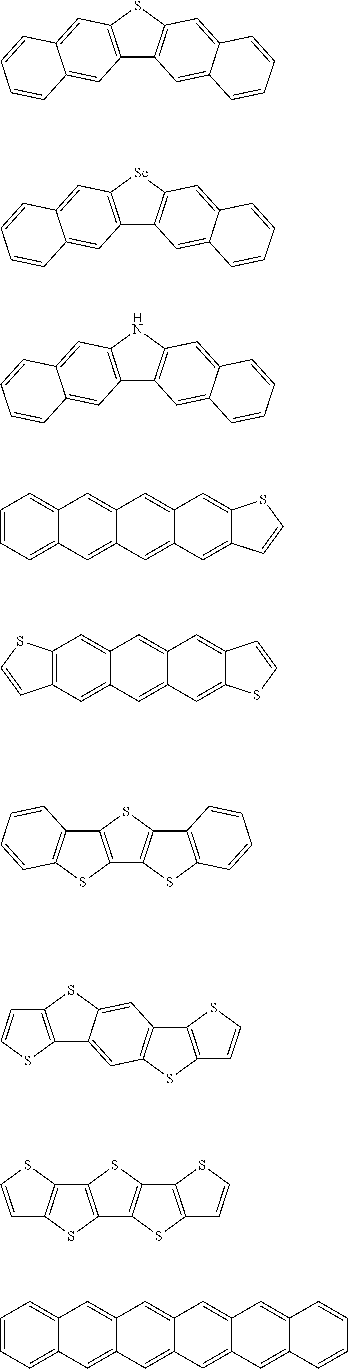

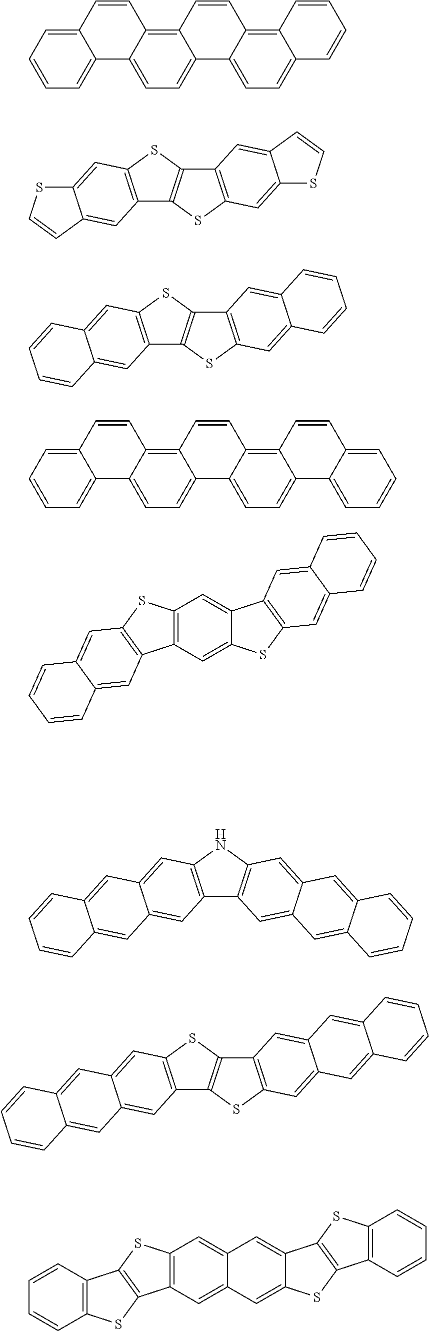

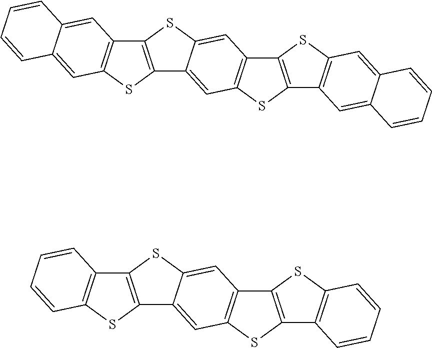 [SMILES: c1ccc2cc3c(cc2c1)sc1c2cc4sc5c6cc7ccccc7cc6sc5c4cc2sc31 ; c1ccc2c(c1)sc1c3cc4sc5c6ccccc6sc5c4cc3sc21]

Among the above specific example, the structure in which thiophene rings are fused with each other and the structure in which thiophene rings and benzene rings are fused with each other are thioacene structures.

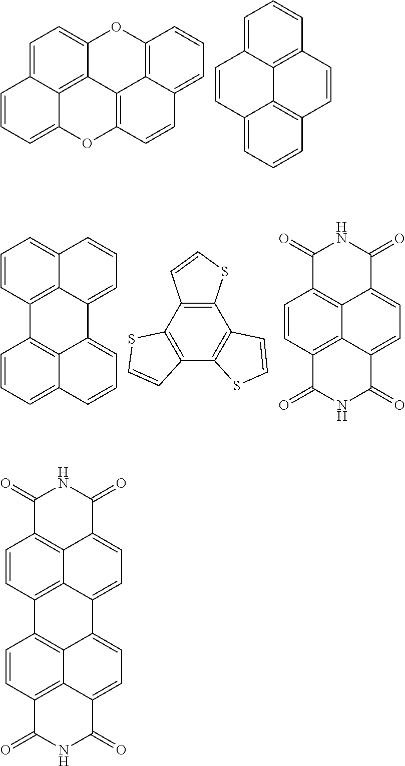

In Formula A-1, L each independently represents a phenylene group or a thienylene group. The thienylene group is a group obtained by removing two hydrogen atoms from thiophene. When m is equal to or greater than 2 and/or n is equal to or greater than 2, a plurality of L's may be the same as or different from each other. The phenylene group is preferably bonded to T and L or Z in a para-position. The thienylene group is preferably bonded to T and L or Z in a 2-position and a 5-position.

In Formula A-1, m represents an integer of 0 to 4. In a case where T does not have a ring-fused structure including 5 or more rings, that is, in a case where T is a group having a ring-fused structure including 3 or 4 rings, m represents an integer of 1 to 4. m is preferably an integer of 1 to 3, more preferably 1 or 2, and even more preferably 1. In a case where T does not have a ring-fused structure including 5 or more rings, if m is 0, the mobility is low, and sufficient driving stability is not obtained.

In a case where T has a ring-fused structure including 5 or more rings, m represents an integer of 0 to 4. m is preferably an integer of 0 to 2, more preferably 0 or 1, and even more preferably 0.

In Formula A-1, Z represents a group represented by Formula a-1 described above. That is, Z represents an alkoxyalkyl group. p represents an integer of 1 to 20. p is preferably an integer of 1 to 16, more preferably an integer of 1 to 8, and even more preferably an integer of 1 to 6.

q represents an integer of 0 to 20. q is preferably an integer of 0 to 16, more preferably an integer of 0 to 8, and even more preferably an integer of 0 to 6.

In Formula A-1, n represents an integer of 1 to 8. n is the number of monovalent groups represented by -(L)ₘ—Z substituting T. In a case where T does not have a ring-fused structure including 5 or more rings, that is, in a case where T is a group having a ring-fused structure including 3 or 4 rings, n represents an integer of 2 to 8. n is preferably an integer of 2 to 6, more preferably an integer of 2 to 4, and even more preferably 2. In a case where T does not have a ring-fused structure including 5 or more rings, if n is 1, sufficient driving stability is not obtained.

In a case where T has a ring-fused structure including 5 or more rings, n represents an integer of 1 to 8. n is preferably an integer of 1 to 4, more preferably 1 or 2, and even more preferably 2.

Component A is preferably an organic semiconductor represented by the following Formula A-2.

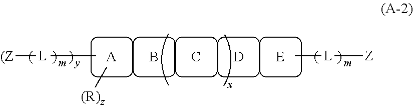

In Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L represents a phenylene group or a thienylene group; Z represents a group represented by Formula a-1 described above; m represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of rings A to E is C₂, C₂ᵥ, or C₂ₕ. When there are a plurality of m's, m's may be the same as or different from each other.

In Formula A-2, rings A to E each independently represent a benzene ring or a thiophene ring. It is preferable that 2 to 4 rings among rings A to E are thiophene rings.

x represents an integer of 1 to 3. That is, rings A to E have a ring-fused structure including 5 to 7 rings.

y represents 0 or 1, and is preferably 1.

z represents 0 or 1, and is preferably 0.

In Formula A-2, the monovalent group represented by -(L)ₘ—Z substitutes ring E on a terminal of the condensed polycyclic aromatic group constituted with rings A to E. Furthermore, either or both of the monovalent group represented by -(L)ₘ—Z and R substitute ring A present on the other terminal. In the organic semiconductor represented by Formula A-2, when y is 1, z is preferably 0, and when y is 0, z is preferably 1.

In Formula A-2, R represents an alkyl group, an alkenyl group, an alkynyl group, an aromatic hydrocarbon group, an aromatic heterocyclic group, or a fluorine atom. The alkyl group may be linear, branched, or cyclic, and is preferably linear. The alkyl group preferably has 1 to 20 carbon atoms, more preferably has 1 to 12 carbon atoms, and even more preferably 1 to 8 carbon atoms. The alkenyl group preferably has 2 to 20 carbon atoms, more preferably 2 to 12 carbon atoms, and even more preferably 2 to 8 carbon atoms. The alkynyl group preferably has 2 to 20 carbon atoms, more preferably has 2 to 12 carbon atoms, and even more preferably has 2 to 8 carbon atoms. The alkenyl group and the alkynyl group may be linear, branched, or cyclic, and are preferably linear. The aromatic hydrocarbon group preferably has 6 to 30 carbon atoms, more preferably has 6 to 20 carbon atoms, and even more preferably has 6 to 10 carbon atoms. The aromatic hydrocarbon group is particularly preferably a phenyl group. The aromatic heterocyclic group preferably has at least one heteroatom selected from the group consisting of a sulfur atom, an oxygen atom, a nitrogen atom, and a selenium atom, and more preferably has a heteroatom selected from the group consisting of a sulfur atom, a nitrogen atom, and an oxygen atom. The heterocyclic group may be monocyclic or polycyclic, and is preferably a 5- to 30-membered ring, more preferably 5- to 20-membered ring, and even more preferably a 5- to 10-membered ring.

Among these, R is preferably an alkyl group, and particularly preferably a linear alkyl group.

It is preferable that, in the organic semiconductor represented by Formula A-2, rings A and E are thiophene rings and/or L is a thienylene ring and m is an integer of 1 to 4. That is, the group represented by Formula a-1 is preferably substituting a thiophene ring.

In Formula A-2, the symmetry of the ring-fused structure formed of rings A to E is C₂, C₂ᵥ, or C₂ₕ. If the symmetry is C₂, C₂ᵥ, or C₂ₕ, a well-ordered crystal structure is easily obtained, and high mobility is easily exhibited.

Regarding the symmetry of a ring-fused structure, the description of “Molecular Symmetry and Theory of Groups” (Masao Nagazaki, Tokyo Kagaku Dojin) can be referred to.

Examples of Component A will be shown below, but the present invention is not limited to the examples.

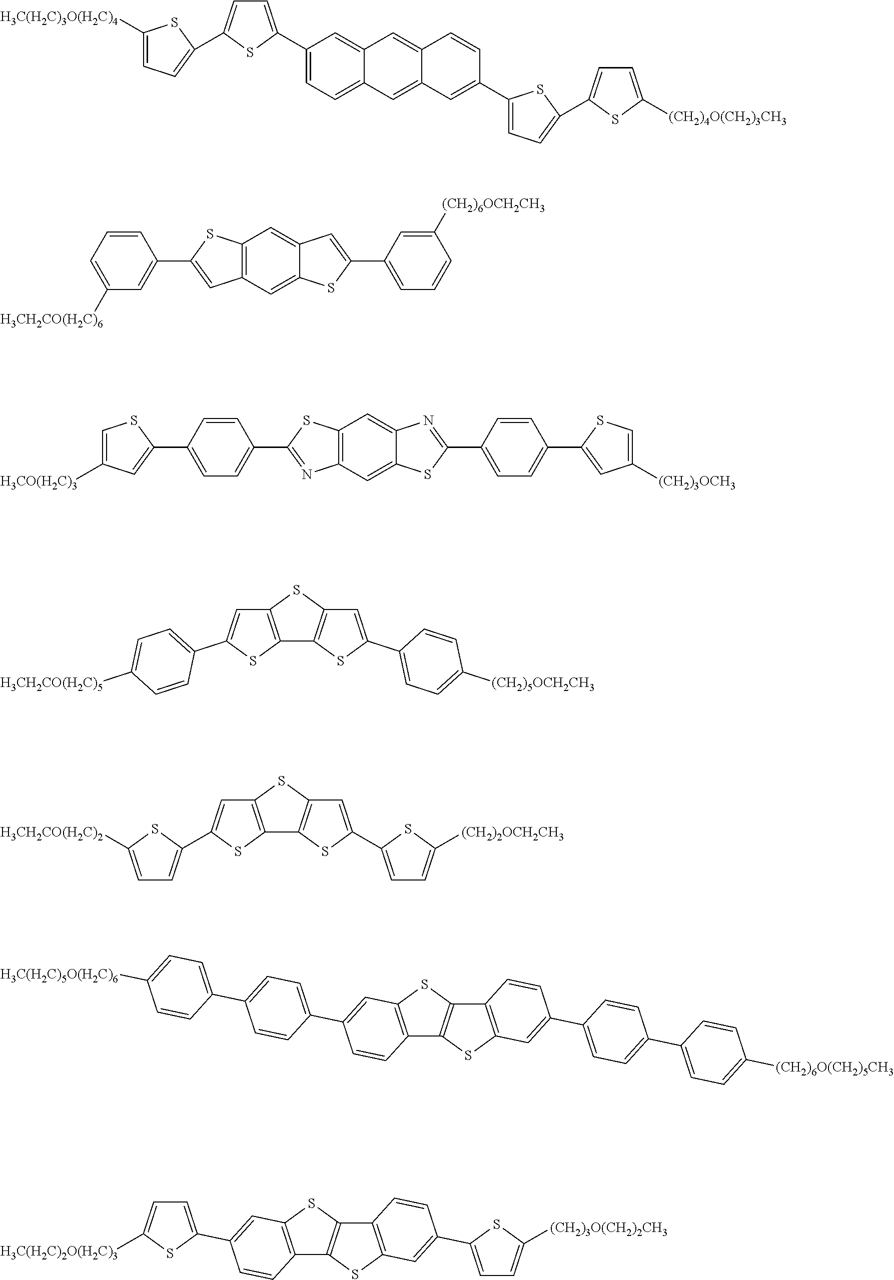

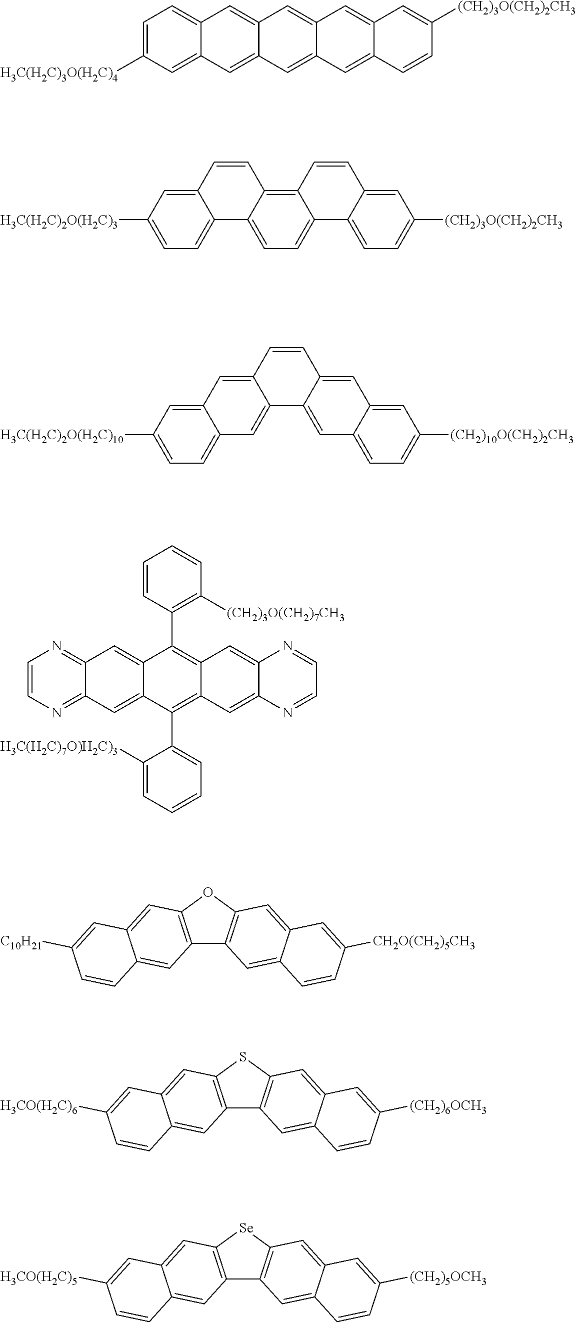

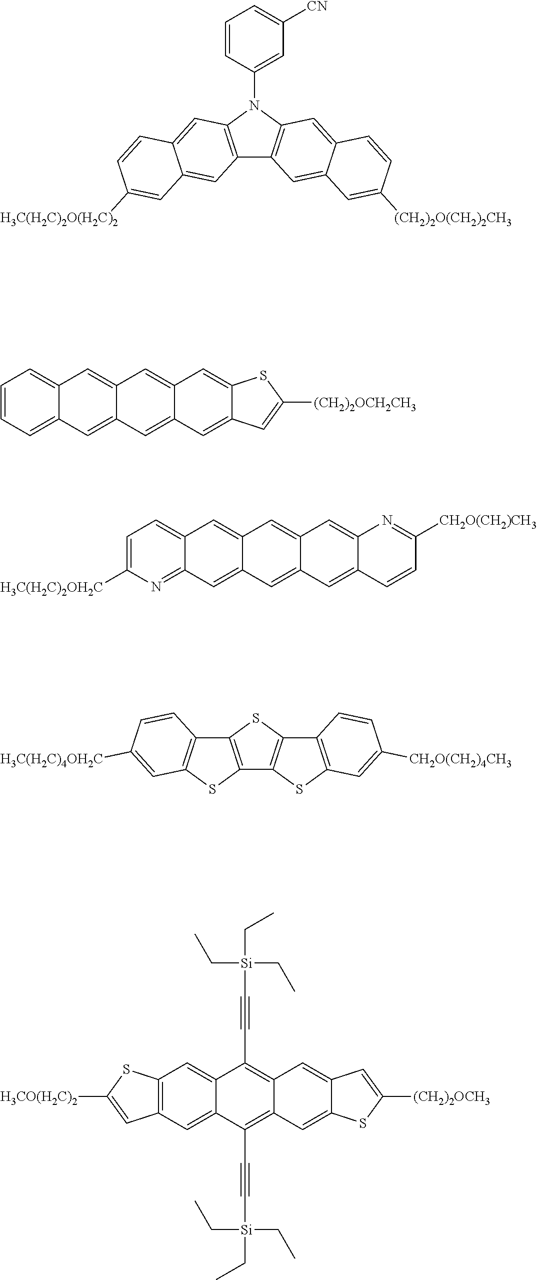

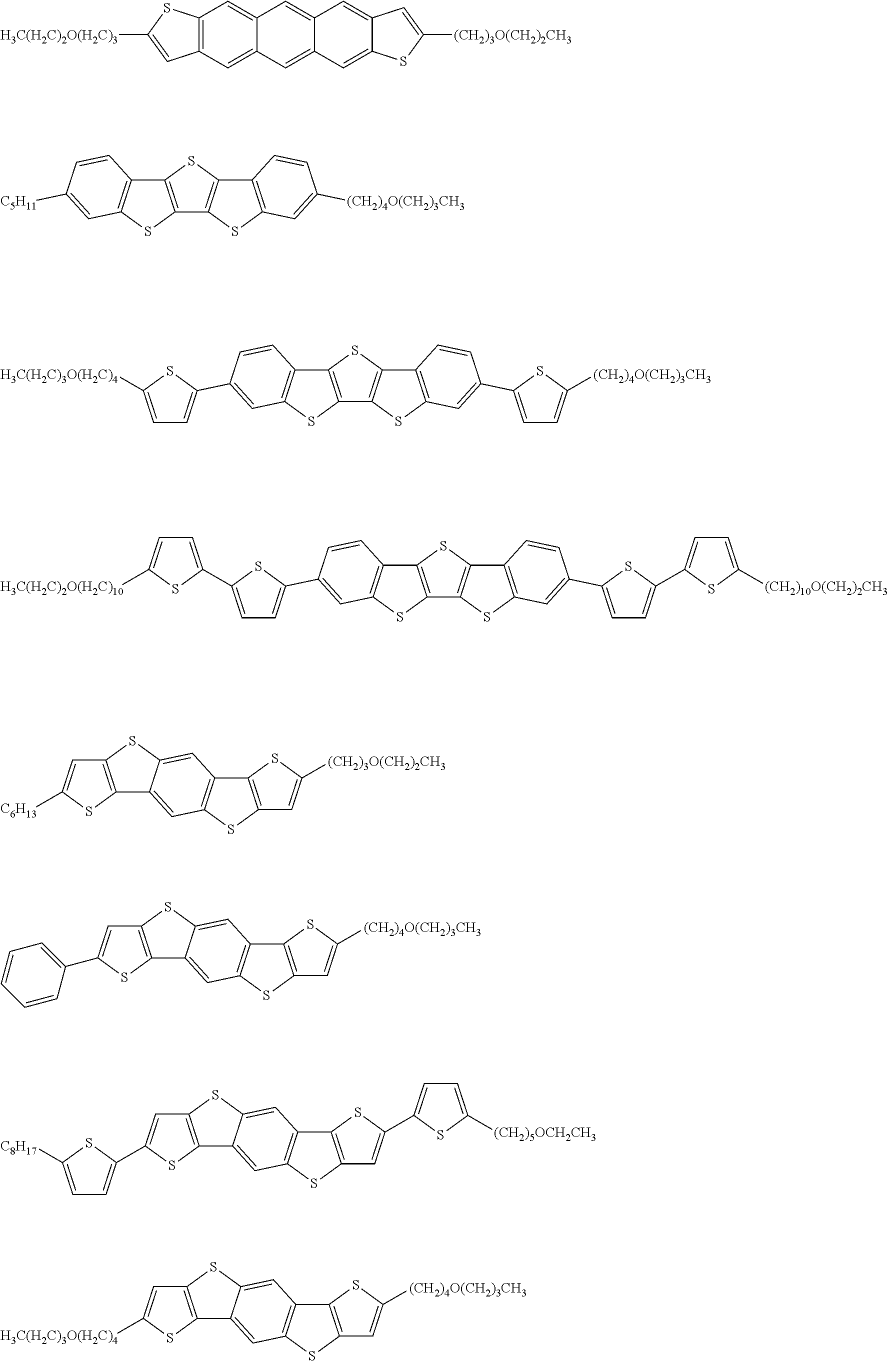

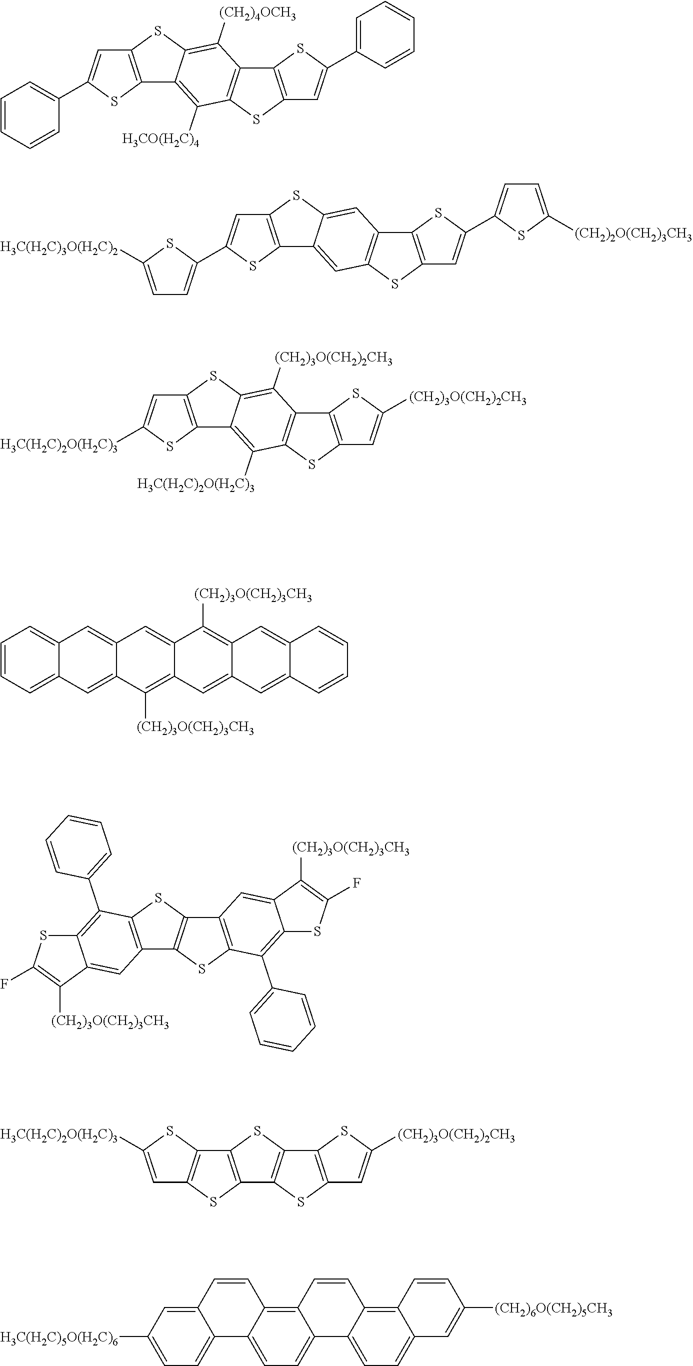

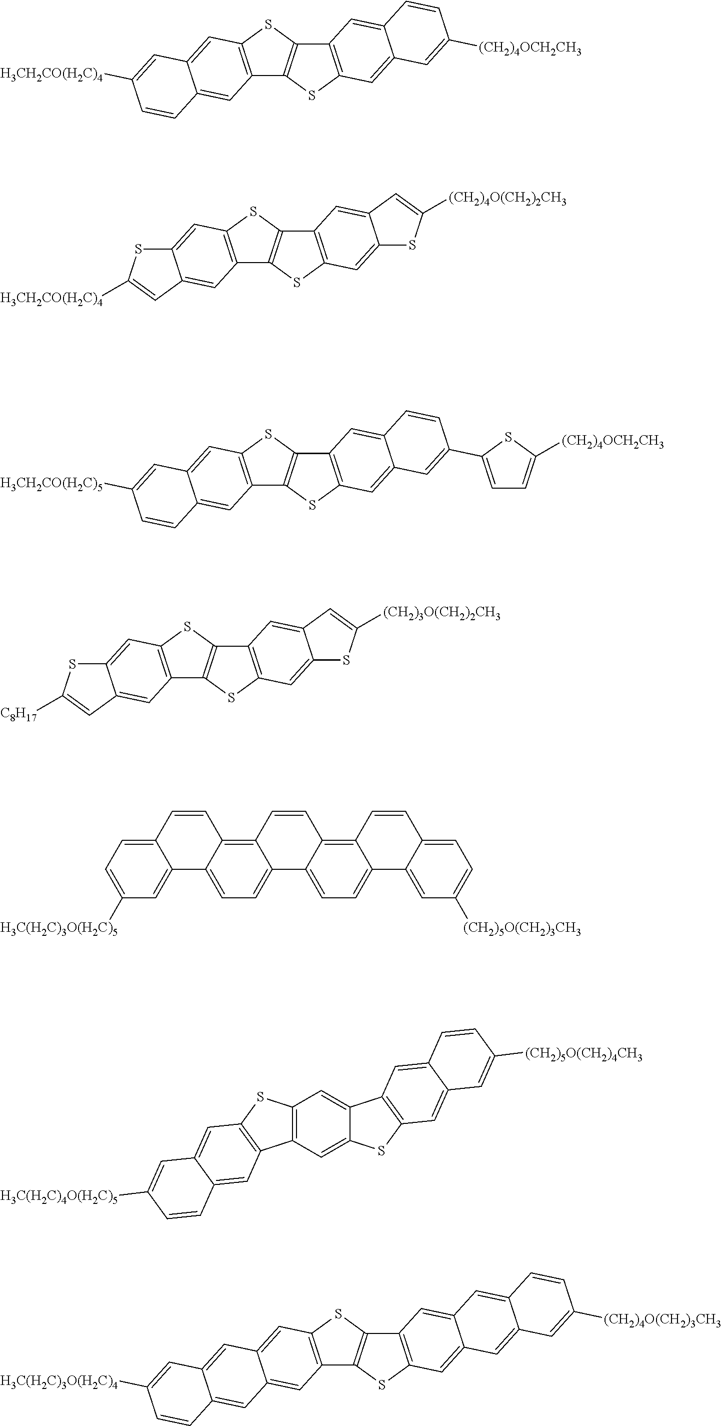

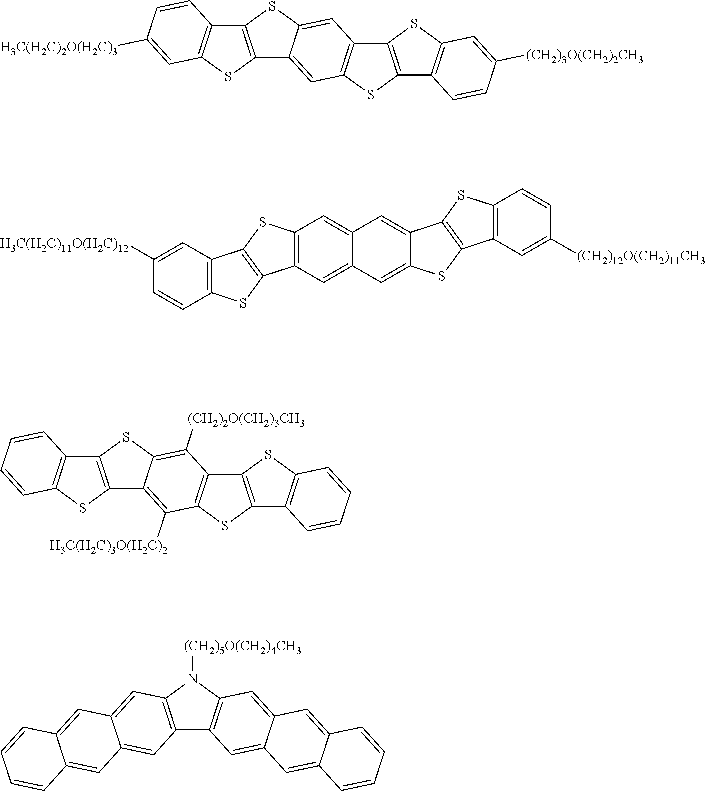

The molecular weight of Component A is not particularly limited, but is preferably equal to or less than 1,500, more preferably equal to or less than 1,000, and even more preferably equal to or less than 800. If the molecular weight is equal to or less than the aforementioned upper limit, the solubility of Component A in a solvent can be improved. In contrast, from the viewpoint of the qualitative stability of a thin film, the molecular weight is preferably equal to or greater than 400, more preferably equal to or greater than 450, and even more preferably equal to or greater than 500.

One kind of Component A may be used singly, or two or more kinds thereof may be used in combination.

The method for manufacturing Component A is not particularly limited, and Component A can be synthesized with reference to known methods. Specifically, it is possible to refer to JP2013-191821A, JP2009-246140A, JP2011-32268A, JP2009-54810A, JP2011-526588A, JP2012-510454A, JP2010-520241A, JP2010-6794A, JP2006-176491A, US2008/0142792A, WO2010/098372A, Adv. Mater. 2013, 25, 6392., Chem. Commun. 2014, 50, 5342., Appl. Phys. Express, 2013, 6, 076503., and Scientific Reports 2014, 4, 5048.

The content of Component A in the composition for forming an organic semiconductor film of the present invention is, with respect to the total amount of the solid content, more preferably 90% to 100% by mass, and even more preferably 95% to 100% by mass. In a case where the composition contains Component C and/or Component D which will be described later, the content of Component A is, with respect to the total amount of the solid content, preferably 50% to 99.5% by mass, and more preferably 70% to 99% by mass.

The content of Component A in the composition for forming an organic semiconductor film of the present invention is, with respect to the total amount of the composition for forming an organic semiconductor film, preferably equal to or greater than 0.1% by mass and less than 15% by mass, and more preferably equal to or greater than 0.2% by mass and equal to or less than 10% by mass. In a case where the content of Component A is equal to or greater than 0.1% by mass, it is possible to obtain an organic semiconductor film and an organic semiconductor element having high mobility and driving stability. In a case where the content of Component A is less than 15% by mass, the storage stability of the composition for forming an organic semiconductor film becomes excellent.

<Component B: solvent having boiling point of equal to or higher than 150° C. and equal to or lower than 300° C. and SP value of equal to or higher than 15.0 and equal to or lower than 18.0>

The composition for forming an organic semiconductor film of the present invention contains a solvent (hereinafter, referred to as specific solvent as well), which has a boiling point of equal to or higher than 150° C. and equal to or lower than 300° C. and an SP value of equal to or higher than 15.0 and equal to or lower than 18.0, as Component B.

The specific solvent has a boiling point of equal to or higher than 150° C. In a case where the boiling point is equal to or higher than 150° C., a composition for forming an organic semiconductor film is obtained which makes it possible to obtain an organic semiconductor element having high mobility and is excellent in film formability.

The boiling point of the specific solvent is preferably equal to or higher than 165° C., more preferably equal to or higher than 175° C., and even more preferably equal to or higher than 185° C. From the viewpoint of removing the solvent, the boiling point of the specific solvent is equal to or lower than 300° C., preferably equal to or lower than 280° C., and more preferably equal to or lower than 260° C.

The SP value (MPa^{1/2}) of the specific solvent is equal to or higher than 15.0 and equal to or lower than 18.0. In a case where the SP value is within the above range, the wettability of the composition becomes excellent. Furthermore, by using the solvent in combination with Component D, the wettability of the composition is further improved.

The SP value of the specific solvent is preferably 15.5 to 17.6, and more preferably 16.5 to 17.6.

In the present invention, “SP value” means “value of solubility parameter”. The SP value mentioned in the present invention is a Hansen solubility parameter determined by the equation explained in “Hansen Solubility Parameters: A User's Handbook, Second Edition, C. M. Hansen (2007), Taylor and Francis Group, LLC (HSPiP manual). The value calculated by the following equation by using “Hansen Solubility Parameters in Practice HSPiP, 3^{rd} Edition” (software version 4. 0. 05) is used as the SP value.

(SP value)²=(δHd)²+(δHp)²+(δHh)²

Hd: contribution to dispersion

Hp: contribution to polarity

Hh: contribution to hydrogen bonding

In the present invention, the specific solvent preferably has an aliphatic ring structure or an aromatic ring structure in a molecule. Examples of the aliphatic ring structure include a cyclohexane ring or a decalin ring. Examples of the aromatic ring structure include a benzene ring. In a case where the specific solvent has an aliphatic ring structure or an aromatic ring structure in a molecule, the solubility of Component A becomes excellent, and the wettability becomes excellent.

The solvents preferred as Component B in the present invention will be shown below together with the boiling point and the SP value thereof.

Decane (boiling point: 174° C., SP value: 15.7), propyl cyclohexanone (boiling point: 157° C., SP value: 16.2), cis-decalin (boiling point: 196° C., SP value: 16.8), amyl benzene (boiling point: 205° C., SP value: 17.5), butoxybenzene (boiling point: 210° C., SP value: 17.5), m-diethylbenzene (boiling point: 181° C., SP value: 17.7), benzyl butyl ether (boiling point: 222° C., SP value: 17.8), 4-tert-butylanisole (boiling point: 222° C., SP value: 17.8)

Among these, cis-decalin or amyl benzene is preferable, and cis-decalin is more preferable.

One kind of Component B may be used singly, or two or more kinds thereof may be used in combination.

Component B may be appropriately added such that the content of Component A in the composition for forming an organic semiconductor film and the amount of total solid content thereof which will be described later fall into a desired range.

In the present invention, the composition for forming an organic semiconductor film may contain a solvent other than the specific solvent as a solvent. Provided that the total content of the solvents is 100 parts by mass, the content of the specific solvent is preferably equal to or greater than 50 parts by mass, more preferably equal to or greater than 70 parts by mass, and even more preferably equal to or greater than 90 parts by mass. It is particularly preferable that the specific solvent is the only solvent contained in the composition for forming an organic semiconductor film.

<Component C: Polymer>

The composition for forming an organic semiconductor film of the present invention may contain a polymer as Component C.

Furthermore, the organic semiconductor film and the organic semiconductor element of the present invention may be an organic semiconductor element having a layer containing Component A described above and a layer containing the polymer.

The type of polymer is not particularly limited, and known polymers can be used. Examples of the polymer include an insulating polymer such as polystyrene, polycarbonate, polyarylate, polyester, polyamide, polyimide, polyurethane, polysiloxane, polysulfone, polymethyl methacrylate, polymethyl acrylate, cellulose, polyethylene, or polypropylene and a copolymer of these, a semiconductor polymer such as polysilane, polycarbazole, polyarylamine, polyfluorene, polythiophene, polypyrrole, polyaniline, polyparaphenylene vinylene, polyacene, or polyheteroacene and a copolyme of these, rubber, and thermoplastic elastomer.

Among these, as the polymer, a benzene ring-containing polymer compound (polymer having a benzene ring group-containing monomer unit) is preferable. The content of the benzene ring group-containing monomer unit is not particularly limited, but is preferably equal to or greater than 50 mol %, more preferably equal to or greater than 70 mol %, and even more preferably equal to or greater than 90 mol % with respect to all of the monomer units. The upper limit of the content is not particularly limited and is, for example, 100 mol %.

Examples of the aforementioned polymer include polystyrene, poly(a-methylstyrene), polyvinyl cinnamate, poly(4-vinylphenyl), poly(4-methyl styrene), poly[bis(4-phenyl)(2,4,6-trimethylphenyl)amine], poly[2,6-(4,4-bis(2-ethylhexyl)-4H cyclopenta[2,1-b;3,4-b′]dithiophene)-alt-4,7-(2,1,3-benzothiadiazole)], and the like. Among these, poly(a-methyl styrene) is particularly preferable.

The weight-average molecular weight of the polymer is not particularly limited, but is preferably 1,000 to 2,000,000, more preferably 3,000 to 1,000,000, and even more preferably 5,000 to 600,000.

It is preferable that, in Component B, the solubility of the polymer is higher than the solubility of Component A. If this aspect is adopted, the mobility and heat stability of the obtained organic semiconductor are further improved.

The content of the polymer in the composition for forming an organic semiconductor film of the present invention is, with respect to 100 parts by mass of the content of Component A, preferably 1 to 10,000 parts by mass, more preferably 10 to 1,000 parts by mass, even more preferably 25 to 400 parts by mass, and most preferably 50 to 200 parts by mass. If the content is within the above range, the mobility and film uniformity of the obtained organic semiconductor are further improved.

As the weight-average molecular weight, a value is used which is measured by a gel permeation chromatography (GPC) method and expressed in terms of standard polystyrene.

<Component D: Silicone Compound Having Structure Represented by Formula D-1>

The composition for forming an organic semiconductor film of the present invention preferably contains a silicone compound having a structure represented by the following Formula D-1 as Component D.

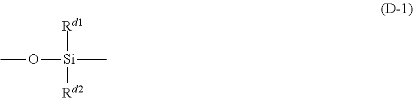

In Formula D-1, R^{d1} and R^{d2} each independently represent a monovalent hydrocarbon group which does not contain an ether bond.

In Formula D-1, in a case where either or both of R^{d1} and R^{d2} contain an ether bond, either or both of R^{d1} and R^{d2} become a trap, and hence the mobility is reduced.

As the monovalent hydrocarbon group represented by R^{d1} and R^{d2} in Formula D-1, an alkyl group or an aryl group is preferable.

The alkyl group is preferably an alkyl group having 1 to 20 carbon atoms, more preferably an alkyl group having 1 to 12 carbon atoms, even more preferably an alkyl group having 1 to 6 carbon atoms, and particularly preferably an alkyl group having 1 to 4 carbon atoms. The alkyl group may be any of linear, branched, and cyclic alkyl groups, but is preferably a linear or branched alkyl group.

The aryl group is preferably an aryl group having 6 to 20 carbon atoms, more preferably an aryl group having 6 to 14 carbon atoms, even more preferably an aryl group having 6 to 10 carbon atoms, and particularly preferably a phenyl group.

At least one of R^{d1} or R^{d2} is preferably an alkyl group having 2 to 18 carbon atoms or an alkenyl group having 2 to 18 carbon atoms. The alkyl group and the alkenyl group may have a substituent, and examples of the substituent include an aryl group.

Furthermore, at least one of R^{d1} or R^{d2} is preferably an aralkyl group (an alkyl group substituted with an aryl group). As the aryl group that the aralkyl group has is preferably an aryl group having 6 to 20 carbon atoms, more preferably an aryl group having 6 to 14 carbon atoms, even more preferably an aryl group having 6 to 10 carbon atoms, and particularly preferably a phenyl group. An alkylene group that the aralkyl group has is preferably an alkylene group having 1 to 20 carbon atoms, more preferably an alkylene group having 2 to 18 carbon atoms, and particularly preferably an alkylene group having 2 to 12 carbon atoms.

Component D is preferably a compound having a polysiloxane structure. Furthermore, Component D is preferably a silicone compound having a polysiloxane structure that has a structure represented by Formula D-1 described above in at least a portion of the repeating unit.

Component D is preferably a silicone compound having a structure represented by the following Formula D-2.

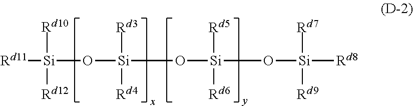

In Formula D-2, R^{d3}, R^{d4}, R^{d5}, and R^{d7} to R^{d12} each independently represent an unsubstituted alkyl group, an unsubstituted aryl group, or an alkyl group substituted with a halogen atom, and R^{d6} represents a monovalent hydrocarbon group which does not contain an ether bond. x and y represent an arbitrary integer.

The unsubstituted alkyl group represented by R^{d3}, R^{d4} R^{d5} and R^{d7} to R^{d12} in Formula D-2 preferably has 1 to 20 carbon atoms, more preferably has 1 to 12 carbon atoms, and even more preferably has 1 to 6 carbon atoms.

The unsubstituted aryl group represented by R^{d3}, R^{d4}, R^{d5} and R^{d7} to R^{d12} in Formula D-2 preferably has 6 to 20 carbon atoms, more preferably has 6 to 14 carbon atoms, and even more preferably has 6 to 10 carbon atoms. The unsubstituted aryl group is particularly preferably a phenyl group.

The alkyl group substituted with a halogen atom preferably has 1 to 20 carbon atoms, more preferably has 1 to 12 carbon atoms, and even more preferably has 1 to 6 carbon atoms. Examples of the halogen atom include a fluorine atom, a chlorine atom, a bromine atom, and an iodine atom. Among these, a fluorine atom is preferable.

A plurality of R^{d3}'s and R^{d4}'s may be the same as or different from each other.

R^{d6} in Formula D-2 is preferably an alkyl group having 2 to 32 carbon atoms or an alkenyl group having 2 to 32 carbon atoms, more preferably an alkyl group having 2 to 24 carbon atoms or an alkenyl group having 2 to 24 carbon atoms, and even more preferably an alkyl group having 2 to 18 carbon atoms or an alkenyl group having 2 to 18 carbon atoms. R^{d6} may be any of linear, branched, or cyclic groups. In a case where R^{d6} represents an unsubstituted alkyl group, the alkyl group is preferably a linear alkyl group having 2 to 32 carbon atoms, more preferably a linear alkyl group having 8 to 18 carbon atoms, and even more preferably a linear alkyl group having 12 to 18 carbon atoms.

The alkyl group is preferably an aralkyl group formed in a case where an alkyl group is further substituted with an aryl group. In a case where R^{d6} is an aralkyl group, the aralkyl group is preferably an aralkyl group having 7 to 32 carbon atoms, more preferably an aralkyl group having 7 to 18 carbon atoms, and even more preferably —CH₂—CH(CH₃)—C₆H₅.

Component D is preferably a silicone compound such as polydimethylsiloxane, poly(dimethylsiloxane-co-methylphenylsiloxane), poly(dimethylsiloxane-co-diphenylsiloxane), or poly(dimethylsiloxane-co-methylalkylsiloxane) and an aralkyl-modified silicone compound obtained in a case where a portion of a methyl group, a phenyl group, or an alkyl group, which is a side chain bonded to a silicon atom of the above silicone compound, is modified with an aralkyl group, and more preferably an aralkyl-modified silicone compound obtained in a case where a portion of a methyl group, a phenyl group, or an alkyl group, which is a side chain bonded to a silicon atom of the above silicone compound, is modified with an aralkyl group.

The viscosity of Component D at 25° C. is preferably 10 to 10,000 mPa·s, more preferably 50 to 5,000 mPa·s, and even more preferably 80 to 1,000 mPa·s. It is preferable that the viscosity of Component D is within the above range, because then the mobility of the obtained organic semiconductor is further improved, and the wettability of the composition for forming an organic semiconductor film is further improved.

The viscosity of Component D is preferably measured by the method based on JIS Z8803.

As Component D, commercially available products may be used. The commercially available products from Shin-Etsu Chemical Co., Ltd, BYK Additives & Instruments, and the like may be appropriately selected and used. Specifically, examples of the products include KF-96-100cs (manufactured by Shin-Etsu Chemical Co., Ltd., polydimethylsiloxane), KF-410 (manufactured by Shin-Etsu Chemical Co., Ltd., aralkyl-modified polydimethylsiloxane), KF-412 (manufactured by Shin-Etsu Chemical Co., Ltd., long-chain alkyl-modified polydimethysiloxane), BYK-322, BYK-323 (all manufactured by BYK Additives & Instruments, aralkyl-modified polymethyl alkylsiloxane), and the like. Among these, KF-410, BYK-322, and BYK-323 are preferable.

The content of Component D is not particularly limited, but is, with respect to 100 parts by mass of Component A, preferably 0.1 to 50 parts by mass, more preferably 0.3 to 30 parts by mass, and even more preferably 0.5 to 25 parts by mass.

The content of Component D is, with respect to the amount of the solid content of the composition for forming an organic semiconductor film of the present invention, preferably 0.01% to 20% by mass, more preferably 0.05% to 10% by mass, and even more preferably 0.1% to 5% by mass.

<Other Components>

The composition for forming an organic semiconductor film of the present invention may contain other components in addition to components A to D.

As other components, known additives and the like can be used.

<Makeup of Composition for Forming Organic Semiconductor Film>

The composition for forming an organic semiconductor film of the present invention contains Component A preferably in an amount of equal to or greater than 0.1% by mass and less than 15% by mass with respect to the total amount of the composition for forming an organic semiconductor film, and contains Component D preferably in an amount of 0 to 50 parts by mass with respect to 100 parts by mass of Component A.

In a case where the composition does not contain Component C, the concentration of the total solid content in the composition for forming an organic semiconductor film of the present invention is preferably equal to or higher than 0.1% by mass. In a case where the composition contains Component C, the concentration is preferably equal to or higher than 1.5% by mass. The solid content is the amount of components excluding a volatile component such as a solvent.

In a case where the composition does not contain Component C, the concentration of the total solid content in the composition for forming an organic semiconductor film is more preferably equal to or higher than 0.2% by mass, and even more preferably equal to or higher than 0.3% by mass.

In a case where the composition contains Component C, the concentration of the total solid content in the composition for forming an organic semiconductor film is more preferably equal to or higher than 2% by mass, and even more preferably equal to or higher than 3% by mass.

The upper limit of the concentration is not limited. However, from the viewpoint of the solubility of Component A or the like, the upper limit is preferably equal to or lower than 20% by mass, more preferably equal to or lower than 15% by mass, and even more preferably equal to or lower than 10% by mass. In a case where the concentration is within the above range, the film formability is further improved, and the mobility of the obtained organic semiconductor is further improved.

<Physical Properties of Composition for Forming Organic Semiconductor Film>

The viscosity of the composition for forming an organic semiconductor film of the present invention is not particularly limited. In view of further improving various printing suitability, particularly, ink jet printing suitability and flexographic printing suitability, the viscosity is preferably 1 to 100 mPa·s, more preferably 1.5 to 50 mPa·s, and even more preferably 2 to 40 mPa·s. The viscosity in the present invention is a viscosity at 25° C.

The viscosity is preferably measured by the method based on JIS Z8803.

<Method for Manufacturing Composition for Forming Organic Semiconductor Film.

The method for manufacturing a composition for forming an organic semiconductor film of the present invention is not particularly limited, and known methods can be adopted. For example, by adding a predetermined amount of Component A to Component B and appropriately stirring the mixture, a desired composition can be obtained. In a case where Component C is used, the composition can be suitably prepared by simultaneously or sequentially adding components A and C.

(Organic Semiconductor Film and Organic Semiconductor Element)

The organic semiconductor film in the present invention is manufactured using the composition for forming an organic semiconductor film of the present invention, and the organic semiconductor element of the present invention is manufactured using the composition for forming an organic semiconductor film of the present invention.

The method for manufacturing the organic semiconductor film or the organic semiconductor element by using the composition for forming an organic semiconductor film of the present invention is not particularly limited, and known methods can be adopted. Examples thereof include a method for manufacturing an organic semiconductor film or an organic semiconductor element by applying the composition onto a predetermined substrate and performing a drying treatment if necessary.

The method for applying the composition onto a substrate is not particularly limited, and known methods can be adopted. Examples thereof include an ink jet printing method, a flexographic printing method, a bar coating method, a spin coating method, a knife coating method, a doctor blade method, a drop casting method, and the like. Among these, an ink jet printing method, a flexographic printing method, a spin coating method, and a drop casting method are preferable, and an ink jet printing method and a flexographic printing method are particularly preferable.

As the flexographic printing method, an aspect in which a photosensitive resin plate is used as a flexographic printing plate is suitably exemplified. By printing the composition onto a substrate according to the aspect, a pattern can be easily formed.

Among these, the method for manufacturing an organic semiconductor film in the present invention and the method for manufacturing an organic semiconductor element of the present invention more preferably include an application step of applying the composition for forming an organic semiconductor film of the present invention onto a substrate, and a removing step of removing a solvent from the applied composition.

The drying treatment in the removing step is a treatment performed if necessary, and the optimal treatment conditions are appropriately selected according to the type of the specific compound and the solvent used. In view of further improving the mobility and heat stability of the obtained organic semiconductor and improving productivity, a heating temperature is preferably 30° C. to 150° C. and more preferably 40° C. to 100° C., and a heating time is preferably 1 to 300 minutes and more preferably 10 to 120 minutes.

The film thickness of the formed organic semiconductor film of the present invention is not particularly limited. From the viewpoint of the mobility and heat stability of the obtained organic semiconductor, the film thickness is preferably 5 to 500 nm and more preferably 20 to 200 nm.

The organic semiconductor film of the present invention can be suitably used in an organic semiconductor element, and can be particularly suitably used in an organic transistor (organic thin film transistor).

The organic semiconductor film of the present invention is suitably prepared using the composition for forming an organic semiconductor film of the present invention.

<Organic Semiconductor Element>

The organic semiconductor element is not particularly limited, but is preferably an organic semiconductor element having 2 to 5 terminals, and even more preferably an organic semiconductor element having 2 or 3 terminals.

Furthermore, the organic semiconductor element is preferably an element which does not use a photoelectric function.

In addition, the organic semiconductor element of the present invention is preferably a non-light emitting organic semiconductor element.

Examples of the 2-terminal element include a rectifier diode, a constant voltage diode, a PIN diode, a Schottky barrier diode, a surge protection diode, a diac, a varistor, a tunnel diode, and the like.

Examples of the 3-terminal element include a bipolar transistor, a Darlington transistor, a field effect transistor, insulated gate bipolar transistor, a uni-junction transistor, a static induction transistor, a gate turn thyristor, a triac, a static induction thyristor, and the like.

Among these, a rectifier diode and transistors are preferable, and a field effect transistor is more preferable.

Examples of the field effect transistor preferably include an organic thin film transistor.

An aspect of the organic thin film transistor of the present invention will be described with reference to a drawing.

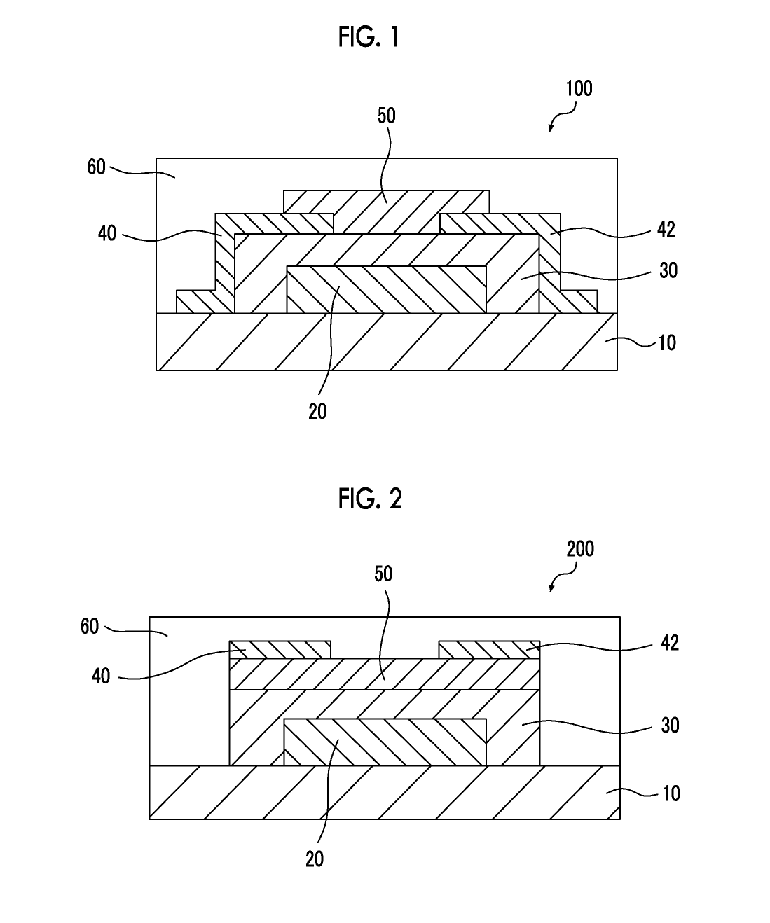

FIG. 1 is a schematic cross-sectional view of an aspect of an organic semiconductor element (organic thin film transistor (TFT)) of the present invention.

In FIG. 1, an organic thin film transistor 100 includes a substrate 10, a gate electrode 20 disposed on the substrate 10, a gate insulating film 30 covering the gate electrode 20, a source electrode 40 and a drain electrode 42 which contact a surface of the gate insulating film 30 that is on the side opposite to the gate electrode 20 side, an organic semiconductor film 50 covering a surface of the gate insulating film 30 between the source electrode 40 and the drain electrode 42, and a sealing layer 60 covering each member. The organic thin film transistor 100 is a bottom gate-bottom contact type organic thin film transistor.

In FIG. 1, the organic semiconductor film 50 corresponds to a film formed of the composition described above.

Hereinafter, the substrate, the gate electrode, the gate insulating film, the source electrode, the drain electrode, the sealing layer, and methods for forming each of these will be specifically described.

[Substrate]

The substrate plays a role of supporting the gate electrode, the source electrode, the drain electrode, and the like which will be described later.

The type of the substrate is not particularly limited, and examples thereof include a plastic substrate, a glass substrate, a ceramic substrate, and the like. Among these, from the viewpoint of applicability to each device and costs, a glass substrate or a plastic substrate is preferable.

Examples of materials of the plastic substrate include a thermosetting resin (for example, an epoxy resin, a phenol resin, a polyimide resin, or a polyester resin (for example, polyethylene terephthalate (PET) or polyethylene naphthalate (PEN)) and a thermoplastic resin (for example, a phenoxy resin, a polyethersulfone, polysulfone, or polyphenylene sulfone).

Examples of materials of the ceramic substrate include alumina, aluminum nitride, zirconia, silicon, silicon nitride, silicon carbide, and the like.

Examples of materials of the glass substrate include soda lime glass, potash glass, borosilicate glass, quartz glass, aluminosilicate glass, lead glass, and the like.

[Gate Electrode, Source Electrode, and Drain Electrode]

Examples of materials of the gate electrode, the source electrode, and the drain electrode include a metal such as gold (Au), silver, aluminum (Al), copper, chromium, nickel, cobalt, titanium, platinum, tantalum, magnesium, calcium, barium, or sodium; a conductive oxide such as InO₂, SnO₂, or indium tin oxide (ITO); a conductive polymer such as polyaniline, polypyrrole, polythiophene, polyacetylene, or polydiacetylene; a semiconductor such as silicon, germanium, or gallium arsenide; a carbon material such as fullerene, carbon nanotubes, or graphite; and the like. Among these, a metal is preferable, and silver and aluminum are more preferable.

A thickness of each of the gate electrode, the source electrode, and the drain electrode is not particularly limited, but is preferably 20 to 200 nm.

The method for forming the gate electrode, the source electrode, and the drain electrode is not particularly limited, but examples thereof include a method of vacuum vapor-depositing or sputtering an electrode material onto a substrate, a method of coating a substrate with a composition for forming an electrode, a method of printing a composition for forming an electrode onto a substrate, and the like. Furthermore, in a case where the electrode is patterned, examples of the patterning method include a photolithography method; a printing method such as ink jet printing, screen printing, offset printing, or relief printing; a mask vapor deposition method; and the like.

[Gate Insulating Film]

Examples of materials of the gate insulating film include a polymer such as polymethyl methacrylate, polystyrene, polyvinylphenol, polyimide, polycarbonate, polyester, polyvinylalcohol, polyvinyl acetate, polyurethane, polysulfone, polybenzoxazole, polysilsesquioxane, an epoxy resin, or a phenol resin; an oxide such as silicon dioxide, aluminum oxide, or titanium oxide; a nitride such as silicon nitride; and the like. Among these materials, in view of the compatibility with the organic semiconductor film, a polymer is preferable.

In a case where a polymer is used as the material of the gate insulating film, it is preferable to use a cross-linking agent (for example, melamine) in combination. If the cross-linking agent is used in combination, the polymer is cross-linked, and durability of the formed gate insulating film is improved.

A film thickness of the gate insulating film is not particularly limited, but is preferably 100 to 1,000 nm.

The method for forming the gate insulating film is not particularly limited, but examples thereof include a method of coating a substrate, on which the gate electrode is formed, with a composition for forming a gate insulating film, a method of vapor-depositing or sputtering the material of the gate insulating film onto a substrate on which the gate electrode is formed, and the like. The method for coating the aforementioned substrate with the composition for forming a gate insulating film is not particularly limited, and it is possible to use a known method (a bar coating method, a spin coating method, a knife coating method, or a doctor blade method).

In a case where the gate insulating film is formed by coating the substrate with the composition for forming a gate insulating film, for the purpose of removing the solvent, causing cross-linking, or the like, the composition may be heated (baked) after coating.

[Polymer Layer]

The organic semiconductor element of the present invention may have a layer containing the aforementioned polymer (hereinafter, referred to as “polymer layer” as well) between the aforementioned organic semiconductor layer and the insulating film. In the above aspect, the organic semiconductor element preferably has the polymer layer between the organic semiconductor layer and the gate insulating film. The film thickness of the polymer layer is not particularly limited, but is preferably 20 to 500 nm. The polymer layer may be a layer containing the aforementioned polymer, and is preferably a layer formed of the aforementioned polymer.

The method for forming the polymer layer is not particularly limited, and known methods (a bar coating method, a spin coating method, a knife coating method, a doctor blade method, and an ink jet method) can be used.

In a case where the polymer layer is formed by performing coating by using a composition for forming a polymer layer, for the purpose of removing a solvent or causing cross-linking, or the like, the composition may be heated (baked) after coating.

[Sealing Layer]

From the viewpoint of durability, the organic semiconductor element of the present invention preferably includes a sealing layer as an outermost layer. In the sealing layer, a known sealant can be used.

The thickness of the sealing layer is not particularly limited, but is preferably 0.2 to 10 μm.

The method for forming the sealing layer is not particularly limited, but examples thereof include a method of coating a substrate, on which the gate electrode, the gate insulating film, the source electrode, the drain electrode, and the organic semiconductor film are formed, with a composition for forming a sealing layer, and the like. Specific examples of the method of coating the substrate with the composition for forming a sealing layer are the same as the examples of the method of coating the substrate with the composition for forming a gate insulating film. In a case where the organic semiconductor film is formed by coating the substrate with the composition for forming a sealing layer, for the purpose of removing the solvent, causing cross-linking, or the like, the composition may be heated (baked) after coating.

FIG. 2 is a schematic cross-sectional view of another aspect of the organic semiconductor element (organic thin film transistor) of the present invention.

In FIG. 2, an organic thin film transistor 200 includes the substrate 10, the gate electrode 20 disposed on the substrate 10, the gate insulating film 30 covering the gate electrode 20, the organic semiconductor film 50 disposed on the gate insulating film 30, the source electrode 40 and the drain electrode 42 disposed on the organic semiconductor film 50, and the sealing layer 60 covering each member. Herein, the source electrode 40 and the drain electrode 42 are formed using the aforementioned composition of the present invention. The organic thin film transistor 200 is a bottom gate-top contact type organic thin film transistor.

The substrate, the gate electrode, the gate insulating film, the source electrode, the drain electrode, the organic semiconductor film, and the sealing layer are as described above.

In FIGS. 1 and 2, the aspects of the bottom gate-bottom contact type organic thin film transistor and the bottom gate-top contact type organic thin film transistor were specifically described. However, the organic semiconductor element of the present invention can also be suitably used in a top gate-bottom contact type organic thin film transistor and a top gate-top contact type organic thin film transistor.

The aforementioned organic thin film transistor can be suitably used in electronic paper, a display device, and the like. Examples

Hereinafter, the present invention will be more specifically described based on examples. The materials and the amount thereof used, the proportion of the materials, the content and procedure of treatments, and the like described in the following examples can be appropriately changed within a scope that does not depart from the gist of the present invention. Accordingly, the scope of the present invention is not limited to the following specific examples. Herein, unless otherwise specified, “part” and “%” are based on mass.

In the following examples and comparative examples, the SP value of Component B was calculated by the following method.

By using “Hansen Solubility Parameters in Practice HSPiP, 3^{rd} Edition” (software version 4. 0. 05), the SP value was calculated by the following equation.

(SP value)²=(δHd)²+(δHp)²+(δHh)²

Hd: contribution to dispersion

Hp: contribution to polarity

Hh: contribution to hydrogen bonding

(Component A: organic semiconductor represented by Formula A-1)

The structures of OSC1 to OSC6 used in the organic semiconductor layer will be shown below.

OSC1 was synthesized with reference to the method described in JP2009-246140A.

OSC2 was synthesized with reference to the method described in JP2011-32268A.

OSC3 was synthesized with reference to the method described in Adv. Mater. 2013, 25, 6392.

OSC4 was synthesized with reference to the method described in WO2010/098372A.

OSC5 was synthesized with reference to the method described in JP2011-32268A.

OSC6 was synthesized with reference to the method described in WO2010/098372A.

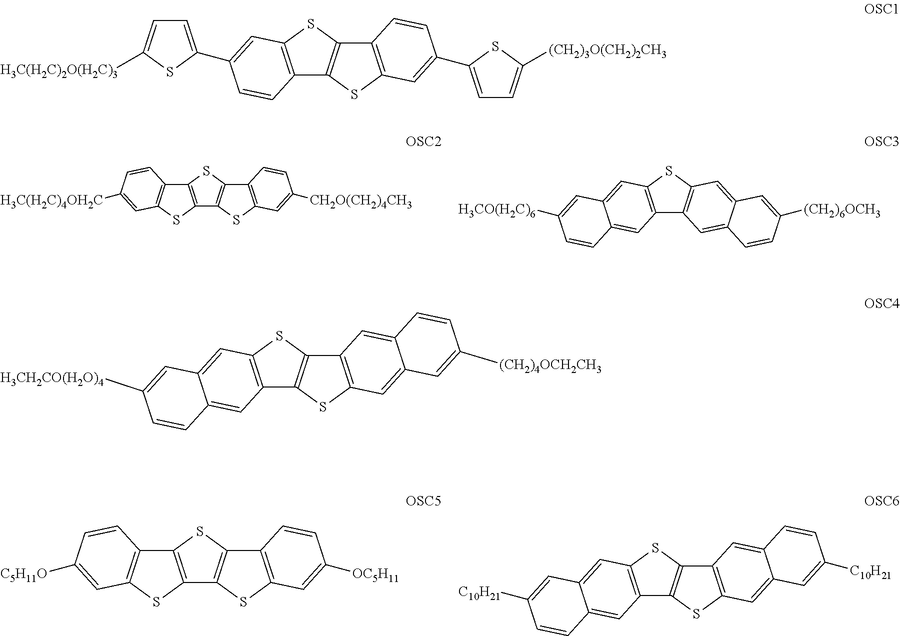

(Component B: Specific Solvent)

The solvents used in examples and comparative examples are shown below.

Octane: boiling point 125° C., SP value 15.5, manufactured by TOKYO CHEMICAL INDUSTRY CO., LTD.

Decane: boiling point 174° C., SP value 15.7, manufactured by TOKYO CHEMICAL INDUSTRY CO., LTD.

cis-Decalin: boiling point 196° C., SP value 16.8, manufactured by TOKYO CHEMICAL INDUSTRY CO., LTD.

Amyl benzene: boiling point 205° C., SP value 17.5, manufactured by TOKYO CHEMICAL INDUSTRY CO., LTD.

m-Diethylbenzene: boiling point 181° C., SP value 17.7, manufactured by TOKYO CHEMICAL INDUSTRY CO., LTD.

1-Chloronaphthalene: boiling point 259° C., SP value 20.8, manufactured by TOKYO CHEMICAL INDUSTRY CO., LTD.

(Component D: Silicone Compound)

KF-410 (aralkyl-modified polydimethylsiloxane (a portion of R^{d1} and R^{d2} is modified with a methylstyryl group (—CH₂—CH(CH₃)—C₆H₅)), manufactured by Shin-Etsu Chemical Co., Ltd.)

KF-412 (long-chain alkyl-modified polydimethylsiloxane, manufactured by Shin-Etsu Chemical Co., Ltd.)

KF-96-100cs (polydimethylsiloxane, weight-average molecular weight: 5,000 to 6,000, manufactured by Shin-Etsu Chemical Co., Ltd.)

(Preparation of Composition for Forming Organic Semiconductor Film)

Component A and Component D described in Table 1 were dissolved in a solvent such that the concentration thereof became as described in Table 1, weighed out into a vial, and stirred and mixed together for 10 minutes by using MIX ROTOR (manufactured by AS ONE Corporation). The mixture was filtered through a 0.5 μm membrane filter, thereby obtaining a composition for forming an organic semiconductor film. The mark “-” in the column of Component D in the table means that Component D was not added.

The concentration of Component A and Component D is a concentration (% by mass) with respect to the total amount of the composition for forming an organic semiconductor film.

(Preparation of Organic Thin Film Transistor (TFT) Element)

Onto a glass substrate (EAGLE XG: manufactured by Corning Incorporated), A1 which will become a gate electrode was vapor-deposited (thickness: 70 nm). The AL was spin-coated with a composition for forming a gate insulating film (PGMEA (propylene glycol monomethyl ether acetate) solution (concentration of solid content: 2% by mass) of polyvinylphenol/melamine=1 part by mass/1 part by mass (w/w)), followed by baking for 60 minutes at 150° C., thereby forming a gate insulating film. Au was vapor-deposited onto the gate insulating film through a mask, thereby forming a source electrode and a drain electrode having a channel length of 50 μm and a channel width of 200 μm. The electrodes were coated with the composition for forming an organic semiconductor film by an ink jet method or a flexographic printing method, thereby forming an organic semiconductor layer. In this way, a bottom gate-bottom contact type organic semiconductor transistor (organic thin film transistor) was obtained.

<Organic Semiconductor Layer: Ink Jet Method>

The substrate on which the aforementioned source and drain electrodes were formed was coated with the prepared composition for forming an organic semiconductor film by an ink jet method. By using DPP 2831 (manufactured by FUJIFILM Dimatix, Inc.) as an ink jet device and a 10 pL head, a solid film was formed by setting a jetting frequency to be 2 Hz and a dot pitch to be 25 μm.

<Organic Semiconductor Layer: Flexographic Printing Method>

The substrate on which the aforementioned source and drain electrodes were formed was coated with the prepared composition for forming an organic semiconductor film by a flexographic printing method. As a printing device, a flexographic printability tester F1 (manufactured by IGT Testing Systems K. K.) was used, and as a flexographic resin plate, AFP DSH 1.70% (manufactured by Asahi Kasei Corporation)/solid image was used. Printing was performed at a transport rate of 0.4 m/sec with applying a pressure of 60 N between the plate and the substrate, and then the substrate was dried as it was for 2 hours at 40° C., thereby preparing an organic semiconductor layer.

(Measurement of Mobility)

Each electrode of the obtained organic thin film transistor was connected to each terminal of a manual prober connected to a semiconductor parameter. analyzer (4155C, manufactured by Agilent Technologies, Inc.), thereby evaluating the field effect transistor (FET). Specifically, by measuring the drain current-gate voltage (Id-Vg) characteristics, the field effect mobility ([cm²/V·s]) was calculated. Based on the value of mobility, the transistors were ranked A to E according to the following evaluation standards. For practical use, a transistor evaluated to be A or B is preferable, and a transistor evaluated to be A is more preferable.

A: equal to or higher than 0.1 cm²/V·s

B: equal to or higher than 0.05 cm²/V·s and less than 0.1 cm²/V·s

C: equal to or higher than 0.01 cm²/V·s and less than 0.05 cm²/V·s

D: equal to or higher than 0.005 cm²/V·s and less than 0.01 cm²/V·s

E: less than 0.005 cm²/V·s

(Measurement of Film Formability)

Regarding the film formability, the inks of the present invention were compared to each other by using a glass substrate (EAGLE XG: manufactured by Corning Incorporated) on which a gate electrode, a gate insulating film, a source electrode, and a drain electrode were formed in the same manner as described above. Onto the substrate, the compositions for forming an organic semiconductor film prepared in Examples 1 to 10 and Comparative Examples 1 to 6 were added dropwise in the same manner as used for preparing the TFT element by an ink jet method. In this way, the composition for forming an organic semiconductor film was supplied onto the substrate, and a semiconductor thin film was obtained. Herein, the wettability was evaluated from the area of the semiconductor thin film formed on the substrate surface, and based on the area (coating rate) covering the substrate, the composition was ranked A to E according to the following evaluation standards. The higher the coating rate, the better the film formability of the composition for forming an organic semiconductor film. For practical use, a composition ranked A or B is preferable, and a composition ranked A is more preferable.

A: coating rate of equal to or higher than 90%

B: coating rate of equal to or higher than 80% and less than 90%

C: coating rate of equal to or higher than 70% and less than 80%

D: coating rate of equal to or higher than 60% and less than 70%

E: coating rate of less than 60%

TABLE 1

| | Component A | | Component B | | Component D | | | |
|---|---|---|---|---|---|---|---|---|
| | | Content | | SP | | Content | Film | |
| | Compound | (% by mass) | Compound | value | Compound | (% by mass) | formability | Mobility |
| Example 1 | OSC1 | 0.5 | cis-Decalin | 16.8 | KF-410 | 0.01 | A | A |
| Example 2 | OSC2 | 0.5 | cis-Decalin | 16.8 | KF-410 | 0.01 | A | A |
| Example 3 | OSC3 | 0.5 | cis-Decalin | 16.8 | KF-410 | 0.01 | A | A |
| Example 4 | OSC4 | 0.5 | cis-Decalin | 16.8 | KF-410 | 0.01 | A | A |
| Example 5 | OSC3 | 0.5 | cis-Decalin | 16.8 | KF-412 | 0.01 | A | A |
| Example 6 | OSC3 | 0.5 | cis-Decalin | 16.8 | KF-96-100cs | 0.01 | A | B |
| Example 7 | OSC3 | 0.5 | cis-Decalin | 16.8 | — | | B | B |
| Example 8 | OSC4 | 0.5 | Amylbenzene | 17.5 | KF-410 | 0.01 | A | A |
| Example 9 | OSC4 | 0.5 | m-Diethylbenzene | 17.7 | KF-410 | 0.01 | A | B |
| Example 10 | OSC4 | 0.5 | Decane | 15.7 | KF-410 | 0.01 | B | A |
| Comparative | OSC3 | 0.5 | Octane | 15.5 | KF-410 | 0.01 | E | D |
| Example 1 | | | | | | | | |
| Comparative | OSC4 | 0.5 | 1-Chloronaphthalene | 20.8 | KF-410 | 0.01 | D | C |
| Example 2 | | | | | | | | |
| Comparative | OSC5 | 0.5 | cis-Decalin | 16.8 | KF-410 | 0.01 | C | D |
| Example 3 | | | | | | | | |
| Comparative | OSC6 | 0.5 | cis-Decalin | 16.8 | KF-410 | 0.01 | D | E |
| Example 4 | | | | | | | | |
| Comparative | OSC5 | 0.5 | Decane | 15.7 | KF-410 | 0.01 | D | D |
| Example 5 | | | | | | | | |
| Comparative | OSC6 | 0.5 | Decane | 15.7 | KF-410 | 0.01 | A | D |
| Example 6 | | | | | | | | |

As shown in Table 1, it was understood that the composition for forming an organic semiconductor film of the present invention makes it possible to obtain an organic semiconductor element having high mobility and is excellent in film formability.

In contrast, it was understood that the composition for forming an organic semiconductor film of comparative examples of the present invention fails to simultaneously accomplish both the mobility of the obtained organic semiconductor element and the film formability.

### EXPLANATION OF REFERENCES

10: substrate

20: gate electrode

30: gate insulating film

40: source electrode

42: drain electrode

50: organic semiconductor film

60: sealing layer

100, 200: organic thin film transistor

What is claimed is:

1. A composition for forming an organic semiconductor film, comprising:
an organic semiconductor represented by the following Formula A-1; and
a solvent, which has a boiling point of equal to or higher than 150° C. and equal to or lower than 300° C. and an SP value of equal to or higher than 15.0 and equal to or lower than 18.0, 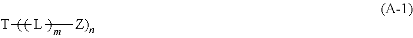
wherein, in Formula A-1, T represents an aromatic hydrocarbon group having a ring-fused structure including 3 or more rings or a heteroaromatic group; L each independently represents a phenylene group or a thienylene group; Z each independently represents a group represented by the following Formula a-1; m each independently represents an integer of 0 to 4; n represents an integer of 1 to 8; and in a case where T does not have a ring-fused structure including 5 or more rings, m represents an integer of 1 to 4, and n represents an integer of 2 to 8, 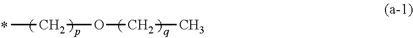
wherein, in Formula a-1, p represents an integer of 1 to 20, q represents an integer of 0 to 20, and * represents a binding position with respect to other structures.

2. The composition for forming an organic semiconductor film according to claim 1, further comprising a silicone compound having a structure represented by the following Formula D-1, 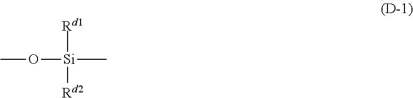
wherein, in Formula D-1, R^{d1} and R^{d2} each independently represent a monovalent hydrocarbon group which does not contain an ether bond.

3. The composition for forming an organic semiconductor film according to claim 2, wherein, in Formula D-1, at least one of R^{d1} or R^{d2} is an alkyl group having 2 to 18 carbon atoms or an alkenyl group having 2 to 18 carbon atoms.

4. The composition for forming an organic semiconductor film according to claim 1, wherein, in Formula A-1, T contains an acene, phenacene, or heteroacene structure having a ring-fused structure including 3 to 7 rings.

5. The composition for forming an organic semiconductor film according to claim 1, wherein the organic semiconductor is an organic semiconductor represented by the following Formula A-2, 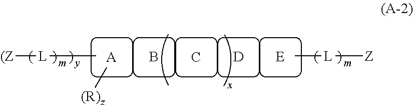
wherein, in Formula A-2, rings A to E each independently represent a benzene ring or a thiophene ring; R represents an alkyl group, an alkenyl group, an alkynyl group, an aromatic hydrocarbon group, an aromatic heterocyclic group, or a fluorine atom; L represents a phenylene group or a thienylene group; Z represents a group represented by Formula a-1; m represents an integer of 0 to 4; when there are two or more L's, L's may be the same as or different from each other; when there are two or more Z's, Z's may be the same as or different from each other; x represents an integer of 1 to 3; y represents 0 or 1; z represents 0 or 1; and the symmetry of a ring-fused structure formed of rings A to E is C₂, C₂ᵥ, or C₂ₕ.

6. The composition for forming an organic semiconductor film according to claim 1, wherein, in Formula a-1, p is an integer of 1 to 6.

7. An organic semiconductor element manufactured using the composition for forming an organic semiconductor film according to claim 1.
